(19) United States
(12) Patent Application Publication
(10) Pub. No.: US 2026/0107806 A1
(43) Pub. Date: Apr. 16, 2026

(54) SEMICONDUCTOR DEVICE WITH STACKED VIAS FOR HEAT REMOVAL

(71) Applicant: INTERNATIONAL BUSINESS MACHINES CORPORATION, ARMONK, NY (US)

(72) Inventors: Keiji Matsumoto, Yokohama-shi (JP); John Knickerbocker, Monroe, NY (US); Mukta Ghate Farooq, Hopewell Junction, NY (US); Todd Edward Takken, Brewster, NY (US); John W. Golz, Hopewell Junction, NY (US)

(21) Appl. No.: 18/917,982

(22) Filed: Oct. 16, 2024

(51) Int. Cl. H01L 23/498; H01L 21/48; H01L 23/00; H01L 23/13; H01L 23/14; H01L 23/15; H01L 23/367; H01L 23/528; H01L 25/065

(52) U.S. Cl. CPC H10W 70/685; H10W 20/427; H10W 40/22; H10W 70/05; H10W 70/65; H10W 70/68; H10W 70/6875; H10W 70/692; H10W 74/15; H10W 90/00; H10W 90/722; H10W 90/724; H10W 90/734

(57) ABSTRACT

A semiconductor device includes a package substrate below a chip, the package substrate including upper build-up layer including a first plurality of power planes (VDD) and ground planes (GND) and a plurality of vias stacked vertically, a core layer, and lower build-up layers including a second plurality of VDD and GND, and a heat spreader layer over the chip. The heat spreader contacts the package substrate on both ends of the package substrate.

### BACKGROUND

### Technical Field

The present disclosure generally relates to semiconductors, and more particularly, to semiconductors with moisture diffusive through glass via structure, and methods of creation thereof.

### Description of Related Art

The continuous miniaturization of transistors and their increasing density on chips are hallmark innovations in the semiconductor industry, closely following Moore's Law. This trend has enabled transistors to shrink to nanometer scales, allowing millions, and even billions, to be integrated onto a single chip. This advancement significantly boosts computational power and energy efficiency. The evolution towards system-on-chip architectures further enhances these capabilities by integrating various functionalities, such as processing and sensing, into a single chip.

### SUMMARY

According to an embodiment, a semiconductor device includes a package substrate below a chip, the package substrate including an upper build-up layers including a first plurality of power planes (VDD) and ground planes (GND) and a plurality of vias stacked vertically, a core layer, and a lower build-up layers including a second plurality of VDD and GND, and a heat spreader layer over the chip. The heat spreader contacts the package substrate on both ends of the package substrate.

In one embodiment, the heat spreader contacts the package substrate through a thermal interface material (TIM).

In one embodiment, the core layer is a metal core, the metal core includes at least one of: Cu, CuMo, CuW, CuC, or graphite.

In one embodiment, the core layer is a ceramic core, the ceramic core includes at least one of: AlN, SiC, BN, or BeO.

In one embodiment, the core layer is a thermal conductor, the thermal conductor includes at least one of: diamond or silicon.

In one embodiment, the plurality of stacked vias is configured to function as at least one of power or ground.

In one embodiment, the upper build-up layers and a core layer further includes signal vias and lines.

In one embodiment, the core layer is ground, and includes a dielectric layer between the power through-holes and the core layer.

In one embodiment, the core layer is power, and includes a dielectric layer between the ground through-holes and the core layer.

In one embodiment, the core layer includes signal-through-holes, and includes a dielectric layer between the signal-through-holes and the core substrate layer.

In one embodiment, vias having a larger diameter compared to other vias are located in hot spot areas.

In one embodiment, the core layer includes materials selected based on at least one of: thermal, mechanical and electrical characteristics, thermal conductivity, CTE, Young's modulus In one embodiment, the core layer includes a set of cuts, wherein the set of cuts are electrically and thermally isolated from each other.

In one embodiment, at least one of a piece of metal or a ceramic or a diamond or a Si is embedded in the upper build-up layers or in the core layer of a package substrate below chips or chiplets.

According to an embodiment, a method of fabricating a semiconductor device includes forming a package substrate below a chip, including forming upper build-up layers including a first plurality of power planes (VDD) and ground planes (GND) and a plurality of vias stacked vertically, forming a core layer, and forming a lower build-up layers including a second plurality of VDD and GND forming a heat spreader over the chip, and establishing thermal connections between the heat spreader and the package substrate on both ends of the package substrate.

In one embodiment, the method includes forming a dielectric layer between a set of contacts and the core layer, the set of contacts includes at least one of: ground, power, or signal-through-holes.

In one embodiment, the core layer is a metal core, the metal core includes at least one of: Cu, CuMo, CuW, CuC, or graphite.

In one embodiment, the core layer is a ceramic core, the ceramic core includes at least one of: AlN, SiC, BN, or BeO.

In one embodiment, the core layer is a thermal conductor, the thermal conductor includes at least one of: diamond or silicon.

According to an embodiment, a semiconductor device include upper build-up layers including a first plurality of power planes (VDD) and ground planes (GND) and a plurality of stacked vias, a core layer, and lower build-up layers including a second plurality of VDD and GND.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1A illustrates a conventional thermal management system for a 3D chip.

FIG. 1B illustrates a cross section view of the power insert in a thermal management system for a 3D chip.

FIG. 2 illustrates a conventional package substrate used for thermal management of a 3D chip.

FIG. 3A illustrates a semiconductor device with a package substrate for thermal management of a 3D chip, in accordance with an embodiment.

FIG. 3B illustrates a cross section view of a package substrate of a semiconductor device for thermal management of a 3D chip, in accordance with an embodiment.

FIG. 4A illustrates a semiconductor device with a package substrate and stacked vias for thermal management of a 3D chip, in accordance with an embodiment.

FIG. 4B illustrates a cross section view of a package substrate and stacked vias of a semiconductor device for thermal management of a 3D chip, in accordance with an embodiment.

FIGS. 5A and 5D illustrate a top view of upper build-up layers for thermal management of a 3D chip, in accordance with an embodiment.

FIG. 5B illustrates a top view of a metal core for thermal management of a 3D chip, in accordance with an embodiment.

FIG. 5C illustrates a top view of lower build-up layers for thermal management of a 3D chip, in accordance with an embodiment.

FIG. 6A illustrates a power map of a 3D chip, in accordance with an embodiment.

FIG. 6B illustrates a top view of the stacked vias locations in upper build-up layers, in accordance with an embodiment.

FIG. 7 illustrates a top view of the metal core of the semiconductor device for thermal management, in accordance with an embodiment.

FIG. 8A illustrates a semiconductor device with electrically insulated thermal interface materials, in accordance with an embodiment.

FIG. 8B illustrates a cross section view of a package substrate of a semiconductor device with electrically insulated thermal interface material, in accordance with an embodiment.

FIGS. 9A-9B illustrate a semiconductor device with compensation of heigh variation of chiplets, in accordance with an embodiment.

FIG. 10A illustrates a cross section view of a semiconductor device with additional heat spreader foots, in accordance with an embodiment.

FIG. 10B illustrates a top view of a semiconductor device with additional heat spreader foots, in accordance with an embodiment.

FIG. 11 illustrates a block diagram of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or active changes may be made without departing from the spirit and scope defined by the claims. The description of the embodiments is not limiting. In particular, elements of the embodiments described hereinafter may be combined with elements of different embodiments.

According to an embodiment, a semiconductor device includes a package substrate below a chip, the package substrate including upper build-up layers including a first plurality of power planes (VDD) and ground planes (GND) and a plurality of vias stacked vertically, a core layer, and lower build-up layers including a second plurality of VDD and GND, and a heat spreader over the chip. The heat spreader contacts the package substrate on both ends of the package substrate. The package substrate with vertically stacked vias and a heat spreader improves heat dissipation from the chip, ensuring effective thermal management.

In one embodiment, the heat spreader contacts the package substrate through a thermal interface material (TIM). Using a thermal interface material (TIM) enhances heat transfer efficiency between the heat spreader and package substrate.

In one embodiment, the core layer is a metal core, the metal core includes at least one of: Cu, CuMo, CuW, CuC, or graphite. A metal core, such as Cu or graphite, provides superior thermal conductivity and mechanical strength.

In one embodiment, the core layer is a ceramic core, the ceramic core includes at least one of: AlN, SiC, BN, or BeO. A ceramic core, like AlN or SiC, offers excellent thermal conductivity and electrical insulation for better heat management.

In one embodiment, the core substrate is a thermal conductor, the thermal conductor includes at least one of: diamond or silicon. Using a thermal conductor like diamond or silicon in the core maximizes heat dissipation due to their exceptional thermal properties.

In one embodiment, the plurality of stacked vias is configured to function as at least one of power or ground. Configuring the stacked vias as power or ground enhances electrical performance and heat dissipation efficiency.

In one embodiment, the upper build-up layers further include signal vias and lines. Including signal vias and lines in the upper build-up layers improves data transmission while maintaining heat management.

In one embodiment, the core layer includes ground planes, and the semiconductor device further includes a dielectric layer between the power through-holes and the core layer. Ground planes in the core substrate, along with a dielectric layer, enhance electrical isolation and device reliability.

In one embodiment, the core layer includes power planes, and the semiconductor device further includes a dielectric layer between the ground through-holes and the core layer. Power planes in the core improve power distribution and thermal management by isolating current paths.

In one embodiment, the core layer includes signal-through-holes, and the semiconductor device further includes a dielectric layer between the signal-through-holes and the core layer. Signal-through-holes in the core ensure efficient signal transmission and electrical isolation for high-performance devices.

In one embodiment, each of the plurality of stacked vias has a diameter ranging from about 0.1 mm to about 1 mm. Vias with larger diameters are located in hot spot areas. Vias with larger diameters in hotspot areas enhance localized heat dissipation, preventing overheating.

In one embodiment, the core layer includes materials selected based on at least one of: a thermal conductivity, mechanical properties, such as a coefficient of thermal expansion, or a Young's modulus and electrical properties. Selecting core materials based on thermal, mechanical, and electrical properties ensures optimal performance and durability.

In one embodiment, the core layer includes a set of cuts, the set of cuts are electrically and thermally isolated from each other. Electrically and thermally isolated cuts in the core improve heat management and reduce parasitic effects.

In some embodiments, a piece of metal or a ceramic or a diamond or a Si is embedded in upper build-up layers or in a core of a package substrate below chips or chiplets. Embedding portions of metal or a ceramic or a diamond or a Si in the upper build-up layers or package substrate provides structural integrity and enhances heat dissipation.

According to an embodiment, a method of fabricating a semiconductor device includes forming a package substrate below a chip, including forming upper build-up layers including a first plurality of power planes (VDD) and ground planes (GND) and a plurality of vias stacked vertically, forming a core layer, and forming lower build-up layers including a second plurality of VDD and GND forming a heat spreader over the chip, and establishing thermal connections between the heat spreader and the package substrate on both ends of the package substrate. thermal connections between the heat spreader and package substrate improve the thermal and electrical performance of the device.

In one embodiment, the method includes forming a dielectric layer between a set of contacts and the core layer, wherein the set of contacts includes at least one of: ground planes, power planes, or signal-through-holes. A dielectric layer between the contacts and core ensures electrical insulation and improves the device's reliability.

In one embodiment, the core substrate layer is a metal core substrate, wherein the metal core substrate includes at least one of: Cu, CuMo, CuW, CuC, or graphite. The use of a metal core substrate like Cu or graphite improves thermal and mechanical stability for enhanced heat dissipation.

In one embodiment, the core layer is a ceramic core substrate, wherein the ceramic core includes at least one of: AlN, SiC, BN, or BeO. A ceramic core offers improved heat resistance and thermal stability, essential for high-performance chips.

In one embodiment, the core layer is a thermal conductor, wherein the thermal conductor includes at least one of: diamond or silicon. Using diamond or silicon as a thermal conductor maximizes heat dissipation, reducing the risk of overheating.

According to an embodiment, a semiconductor device include upper build-up layers including a first plurality of power planes (VDD) and ground planes (GND) and a plurality of stacked vias, a core layer, and lower build-up layers including a second plurality of VDD and GND. 20. Stacked vias in the upper build-up layers enhance the overall electrical performance and heat dissipation in the device.

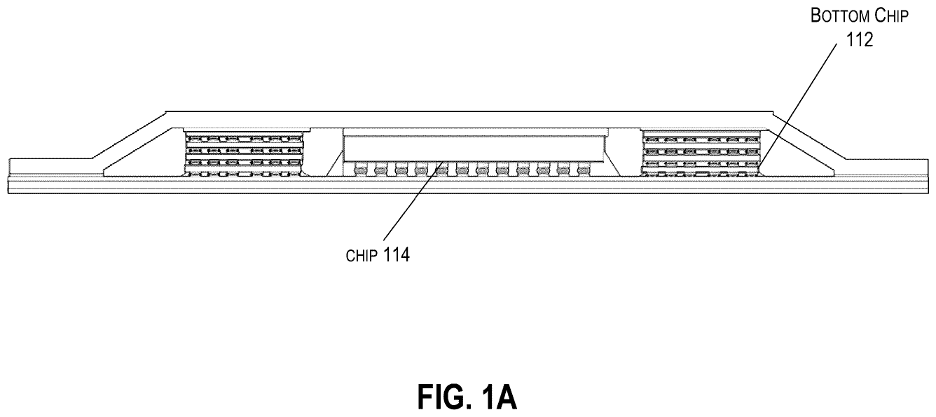

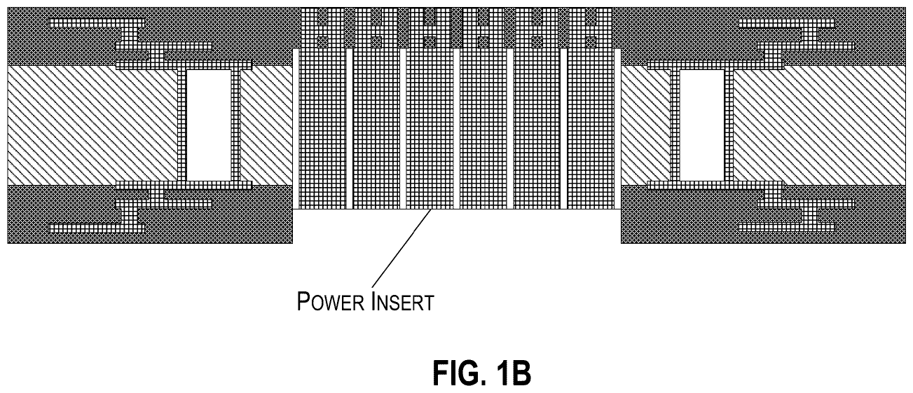

FIG. 1A illustrates a conventional thermal management system for a 3D chip. Generally, thermal management of the bottom chip 112 in a 3D integrated circuit structure presents significant challenges due to the dense stacking of chips and the resulting heat concentration. One approach that has been proposed to address this issue is the use of a power insert, which introduces cooling from the package substrate side. However, this method requires a bottom cold plate, or heatsink, to be directly attached to the bottom of the power insert. This setup is quite different from conventional semiconductor package structures, where cooling solutions are more typically applied to the top of the chip stack rather than the bottom. FIG. 1B illustrates a cross section view of the power insert in a thermal management system for a 3D chip.

A bottom cold plate, while effective in removing heat, complicates the design and increases the complexity of the overall package, deviating from established packaging practices. Utilizing a bottom cold plate involves additional components and potentially increases the cost and manufacturing complexity of the device. Moreover, the presence of a bottom cold plate can limit the form factor and integration flexibility, particularly in systems where space is at a premium or where traditional cooling methods are preferred.

The current disclosure introduces an innovative solution that leverages the beneficial aspects of the power insert for thermal management, but without the need for a bottom cold plate (heatsink). By optimizing the structure and configuration of the power insert, this approach enables efficient thermal dissipation from the bottom chip without resorting to more complex or unconventional cooling mechanisms. This design not only simplifies the packaging structure but also makes the overall solution more practical and compatible with existing manufacturing processes.

From a systems perspective, this approach holds significant value, particularly in environments where 3D integrated circuit is a critical technology. By addressing the thermal management challenges associated with 3D chip stacking without requiring non-standard components such as a bottom cold plate, this disclosure enhances the practicality and scalability of 3Di for a wide range of applications. The solution aligns with the broader industry trend towards higher levels of integration and improved thermal management in advanced semiconductor devices.

Accordingly, the teachings herein provide methods and systems of semiconductor device formation with stacked vias for heat removal. The techniques described herein may be implemented in a number of ways. Example implementations are provided below with reference to the following figures.

### Example Semiconductor Device with Stacked Vias for Heat Removal Structure

Heterogeneous integration (HI) is recognized as an effective means of achieving high-speed and high-bandwidth communication between various chips, including CPUs, GPUs, and memory. Three-dimensional integration (3Di) stands as a significant example of HI, but it presents unique thermal challenges due to its higher heat density compared to conventional two-dimensional packages. The bottom chip in a 3Di structure is particularly prone to thermal management issues because it tends to dissipate more heat than the other layers. This can be because the bottom chip often handles a greater number of electrical interconnects with the substrate, and it is typically a high-functionality component such as a logic chip. The concentration of electrical connections and high functionality leads to increased power consumption, which in turn results in significant heat generation.

In traditional cooling setups, the heat generated by the bottom chip must pass through the entire 3D stack before reaching the cooling elements located on the top side. This arrangement makes it difficult to achieve efficient cooling, as the heat is distributed throughout the stack, which acts as an insulator and limits the cooling potential. As a result, the bottom chip faces greater risk of overheating, which can negatively impact the performance and reliability of the entire system. To address this challenge, the disclosed semiconductor device can manage the heat generated by the bottom chip directly from the package substrate, or laminate, side. This approach would allow the heat to be dissipated more effectively, without needing to pass through the 3D stack. In some embodiments, the disclosed semiconductor device can facilitate cooling from the package substrate side and offer an alternative to the traditional top-side cooling methods, which are less effective in dealing with the thermal demands of the bottom chip in a 3Di configuration.

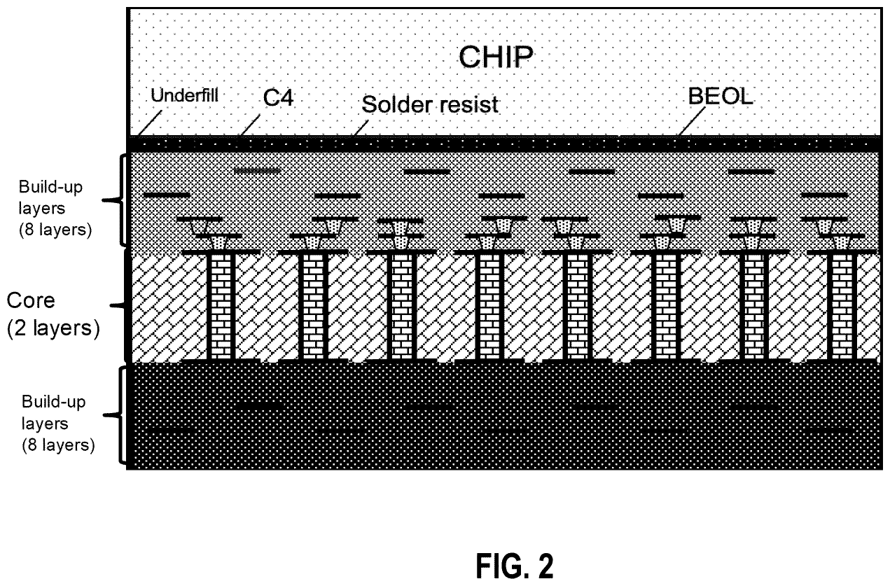

FIG. 2 illustrates a conventional package substrate The conventional package substrate can include a core layer, an upper build up layer and a lower build up layer. The core layer can include epoxy layers, and copper wires coated with resin.

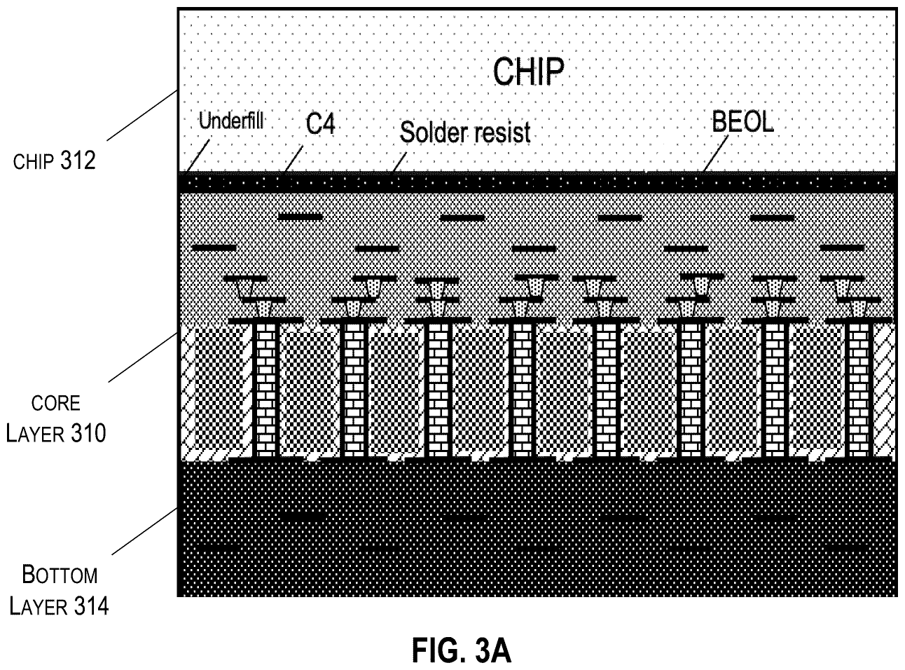

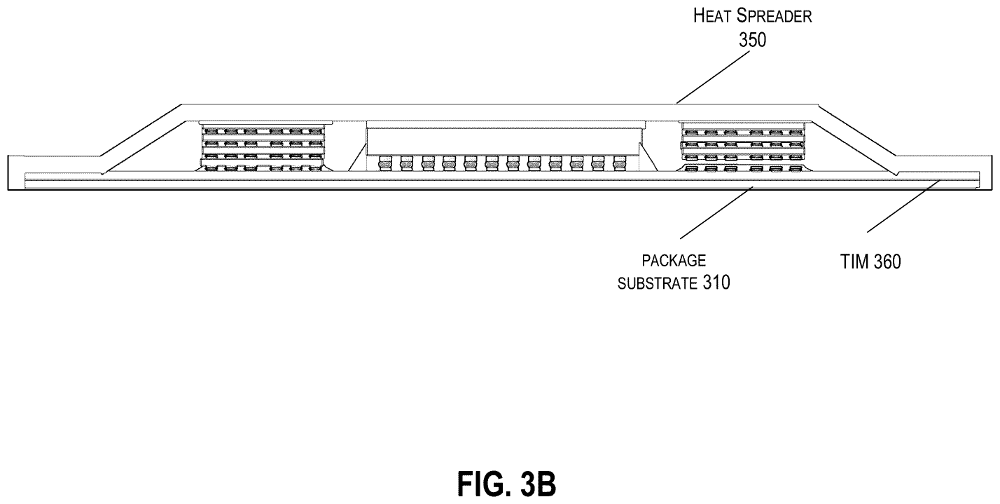

Reference now is made to FIGS. 3A-3B, which are simplified cross-section views of a semiconductor device with a package substrate for thermal management of a 3D chip, consistent with an illustrative embodiment. In various embodiments, the semiconductor device includes a package substrate 310, upper build-up layers 312 and lower build-up layers 314. According to an embodiment, the package substrate 310 is positioned below a chip. The top layer 312 can include upper build-up layers containing a first plurality of power planes, VDD, and ground planes, GND, along with a plurality of vias stacked vertically. The VDD and GND in the top layer 312 can facilitate distributing electrical power and provide a stable ground reference to the chip, ensuring consistent voltage levels and minimizing electrical noise. The vertically stacked vias can serve as conductive pathways that connect different layers within the package substrate 310, facilitating efficient electrical connections and enhancing signal integrity. The package substrate 310 can include a core layer, which can provide structural integrity and can be made from materials optimized for thermal conductivity and mechanical strength. Beneath the core, the bottom layer 314 can include a second plurality of VDD and GND, further improving power distribution and grounding throughout the semiconductor device. Over the chip 316, a heat spreader layer 350 can be placed, which contacts the package substrate 310 on both ends. The heat spreader 350 can effectively conduct heat away from the chip, and by making contact with the package substrate 310 at both ends, the heat spreader 350 can establish a continuous thermal path. Such a configuration can improve heat dissipation from the chip, ensuring effective thermal management and enhancing the device's reliability and performance.

In one embodiment, the heat spreader 350 can contact the package substrate 310 through a thermal interface material, TIM 360. The TIM 360 can fill microscopic air gaps between the surfaces of the heat spreader 350 and the package substrate 310, which would otherwise impede heat transfer due to poor thermal contact. By using a TIM 360, the thermal resistance at the interface can be minimized, which can enhance heat transfer efficiency between the heat spreader 350 and the package substrate 310. Such an improved thermal coupling can ensure that heat generated by the chip is more effectively conducted away, maintaining optimal operating temperatures and preventing thermal-related performance issues or failures.

In one embodiment, the core layer can be a metal core composed of materials such as copper (Cu), copper-molybdenum (CuMo), copper-tungsten (CuW), copper-carbon (CuC), graphite, etc. These materials can be selected based at least in part on their thermal conductivity and mechanical strength. Copper, for example, is renowned for its excellent ability to conduct heat and electricity, which aids in efficient heat dissipation and power distribution within the device. Composites such as CuMo and CuW can combine copper's thermal properties with the mechanical stability of molybdenum or tungsten, enhancing the substrate's ability to withstand mechanical stress and high temperatures. Graphite, while not a metal, can offer high thermal conductivity and can effectively spread heat across the substrate. Incorporating these materials into the core layer 330 can improve the semiconductor device's thermal management capabilities and structural durability, contributing to overall performance and longevity.

In one embodiment, the core layer can be a ceramic core made from materials such as aluminum nitride (AlN), silicon carbide (SiC), boron nitride (BN), or beryllium oxide (BeO). Ceramic materials such as AlN and SiC can offer enhanced thermal conductivity while providing electrical insulation. AlN, for instance, can efficiently conduct heat away from the chip and electrically isolates the chip from other components, preventing unwanted electrical interference. SiC can be used due partly to its high thermal conductivity and mechanical robustness, which makes SiC suitable for high-power and high-temperature applications. BN and BeO can possess high thermal conductivity and act as electrical insulators. Using a ceramic core can enhance heat management and maintains electrical isolation, which ensure reliable operation of high-performance semiconductor devices.

In one embodiment, the core layer can be composed of thermal conductor materials such as diamond or silicon. Diamond possesses one of the highest thermal conductivities among the materials, allowing it to dissipate heat from the chip effectively. Incorporating diamond into the core layer can maximize heat dissipation, significantly reducing the risk of overheating and thermal-induced failures. Silicon possesses high thermal conductivity and is compatible with standard manufacturing processes. Utilizing silicon in the core layer can facilitate efficient heat transfer and maintain material compatibility within the device. By employing materials with high thermal properties, the semiconductor device can enhance its thermal management, leading to improved performance and reliability.

In one embodiment, the plurality of stacked vias is configured to function as power planes or ground planes. By designing the plurality of stacked vias to serve as power distribution paths or ground references, the semiconductor device can enhance electrical performance by providing low-resistance and low-inductance pathways for electrical currents. This configuration can ensure stable voltage levels, minimize power losses, and reduce electrical noise for the proper functioning of the semiconductor device. Additionally, the conductive vias can aid in heat dissipation by transferring heat away from the chip, leveraging their thermal conductivity to improve the device's thermal management.

As shown in FIG. 3B, the core layer can include ground planes, and the semiconductor device can include a dielectric layer between the power plane-through-holes the core layer. The ground planes can provide a stable reference point and help shield the device from electromagnetic interference (EMI). The dielectric layer can act as an electrical insulator between the power plane-through-holes 378 and the conductive core layer 330, preventing electrical short circuits and unwanted interactions. Such an arrangement can enhance electrical isolation, reduces crosstalk, and improves device reliability by ensuring that power and ground paths are properly separated.

In one embodiment, the core layer can include power planes, and the semiconductor device can include the dielectric layer between the ground plane-through-holes and the core layer. Embedding power planes within the core layer can improve power distribution by providing low-resistance pathways and reducing voltage drops. The dielectric layer between the ground plane-through-holes and the core layer can ensure electrical isolation, prevent short circuits and maintain the integrity of the electrical signals. Such a configuration can enhance thermal management by isolating current paths and allows for efficient heat dissipation through the conductive power planes.

In one embodiment, the core layer can include signal-through-holes, and the semiconductor device can include the dielectric layer between the signal-through-holes and the core layer. The signal-through-holes can enable efficient transmission of electrical signals through the core layer. The dielectric layer can provide electrical insulation between the signal-through-holes and the conductive core layer, preventing interference and crosstalk that could degrade signal quality. Such a design can ensure efficient signal transmission and maintain electrical isolation, enhancing the device's performance and reliability.

In one embodiment, the core layer can include materials selected based on properties such as thermal conductivity, mechanical properties, electrical properties, coefficient of thermal expansion (CTE), or Young's modulus. Selecting materials with high thermal conductivity ensures efficient heat dissipation, while appropriate mechanical properties and Young's modulus provide structural integrity and resistance to mechanical stress. Matching the CTE of the core with that of the chip and other components minimizes thermal stress caused by temperature fluctuations, preventing material fatigue and delamination. Considering electrical properties allows for optimal electrical performance and insulation where necessary. By carefully selecting materials based on these properties, the device achieves optimal performance, reliability, and durability.

In one embodiment, the core layer can include a set of cuts 396 that are electrically and thermally isolated from each other. These cuts can segment the substrate into distinct regions, allowing for controlled thermal pathways and electrical isolation between different parts of the device. Electrically isolating these regions can reduce parasitic effects such as crosstalk and electromagnetic interference, which can degrade signal integrity. Thermally isolating the cuts can help manage heat flow within the device, preventing heat from affecting temperature-sensitive components, which can improve heat management and enhances the overall electrical performance of the semiconductor device.

In one embodiment, a piece of metal or a ceramic or a diamond or a Si are embedded in the upper build-up layers or in a core of a package substrate below the chip. Embedding a metal or a ceramic or a diamond or a Si within these layers provides additional structural support and mechanical stability to the device, and enhances heat dissipation by creating direct thermal pathways from the chip through the embedded substrate to other layers, improving overall thermal management. Such an integration can reduce the device's thickness, making it suitable for applications where space is limited, and contributes to the device's reliability and performance.

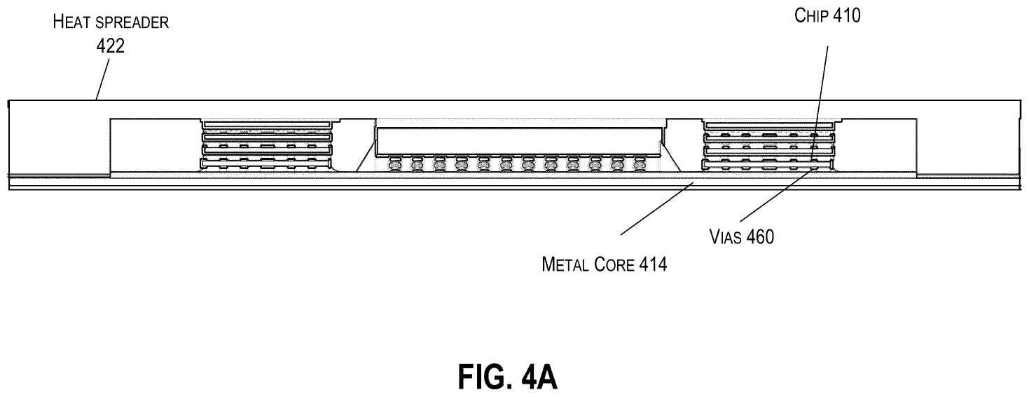

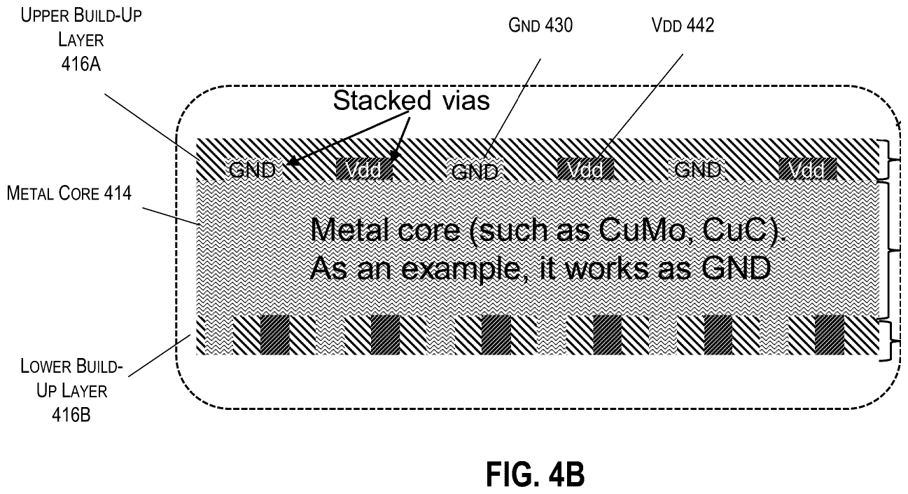

FIG. 4A illustrates a semiconductor device with a package substrate and stacked vias for thermal management of a 3D chip, in accordance with an embodiment. FIG. 4B illustrates a cross section view of a package substrate and stacked vias of a semiconductor device for thermal management of a 3D chip, in accordance with an embodiment. The semiconductor device can employ a combination of stacked vias in the upper build-up layers, a metal core organic substrate (laminate), and organic substrate edge cooling. The stacked vias in the upper build-up layers are vertical conductive pathways that connect different layers within the substrate, providing efficient electrical connections between the chip 410 and the underlying layers. This configuration enhances electrical performance by reducing signal path lengths, minimizing resistance and inductance, and improving signal integrity. The metal core organic substrate 412 can consist of an organic laminate material that incorporates a metal core 414, made of a highly conductive metal such as copper. The metal core 414 can provide thermal conduction, helping to dissipate heat away from the semiconductor chip more effectively than traditional organic substrates. The metal core 414 can further offer mechanical strength and stability, reducing warpage and improving the reliability of the device. The organic substrate edge cooling can be a thermal management technique where the edges of the organic substrate are used to dissipate heat, e.g., by being in thermal contact with a heat sink or cooling structure. By utilizing the edges of the substrate for cooling, heat can be removed not just through the top and bottom surfaces but also laterally, improving overall thermal performance and preventing hotspots.

In one embodiment, the laminate edge cooling via the upper build-up layers can be omitted, allowing a heat spreader to make direct contact with the metal core through a thermal interface material, TIM 420. By removing the upper build-up layers for edge cooling and enabling direct contact between the heat spreader 422 and the metal core 414, thermal resistance is reduced, and heat dissipation is enhanced. The direct path for heat flow can improve the thermal management of the device. Alternatively, the upper build-up layers can be implemented with thermal vias 460—vertical thermal paths that conduct heat—and a heat spreader 422 directly contacts the upper build-up layers through the TIM 420. Incorporating thermal vias in the upper build-up layers can allow heat to be conducted vertically from the chip to the heat spreader 422. Direct contact with the heat spreader 422 through the TIM 420 can enhance thermal coupling, improving heat removal while maintaining the electrical functionality of the upper layers.

In this design, the ground planes, GND 430, in the upper build-up layer 416A are electrically connected with the metal core 414. Electrically connecting the GND 430 to the metal core 414 can create a continuous ground path, reducing electrical resistance and inductance in the ground network, which can improve electrical performance by enhancing signal integrity, reducing noise, and providing effective electromagnetic shielding. On the other hand, the power planes, VDD 432, in the upper build-up layer 416 do not electrically connect with the metal core 414 but are electrically connected with the VDD 442 in the lower build-up layer 416B. By isolating the VDD 432 from the metal core 414, which is connected to ground, electrical short circuits can be prevented, ensuring proper power distribution. Connecting VDD across upper and lower layers can provide consistent power delivery throughout the device.

Additionally, the top layer of the device can function as a redistribution layer (RDL) to reroute electrical connections to desired locations, allowing for the rearrangement of signal, power, and ground connections to match the chip's pad layout to the substrate or package interconnects. Using the top layer as an RDL can provide design flexibility, supports higher interconnect density, and can reduce the overall package size, which is essential for modern, compact electronic devices.

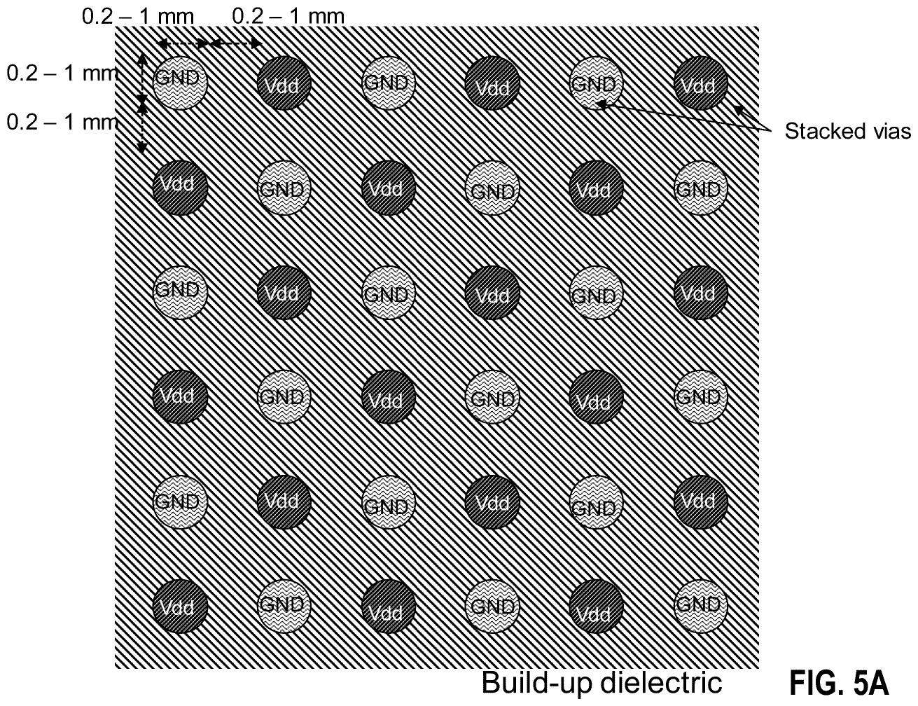

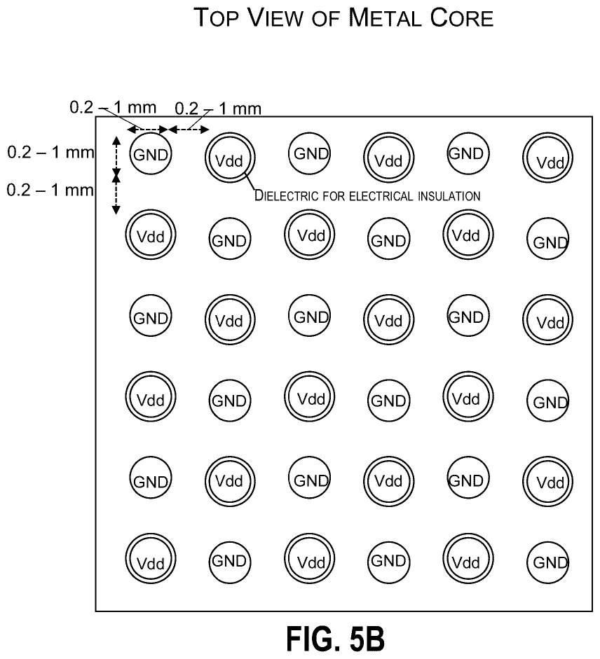

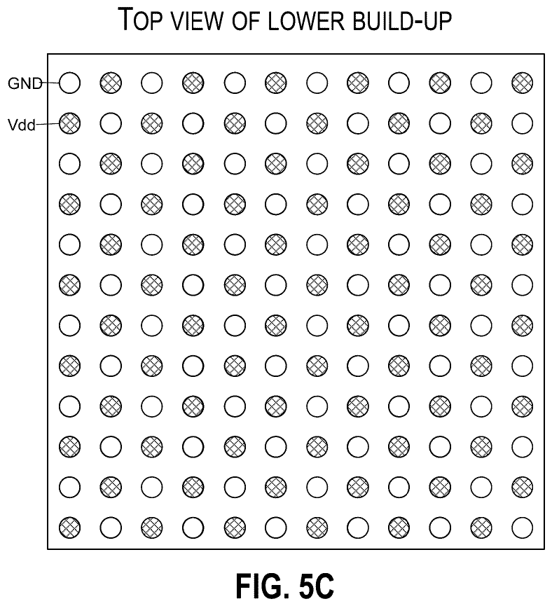

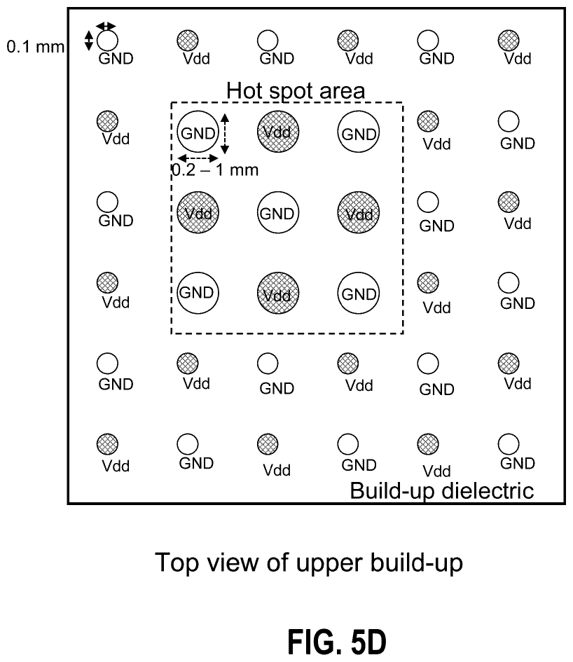

FIGS. 5A-5D illustrate a top view of different layers of a semiconductor device for thermal management of a 3D chip, in accordance with an embodiment. As shown, the diameter of the VDD and GND can be 0.2 mm to 1 mm. The pitch can be 0.2 mm to 1 mm.

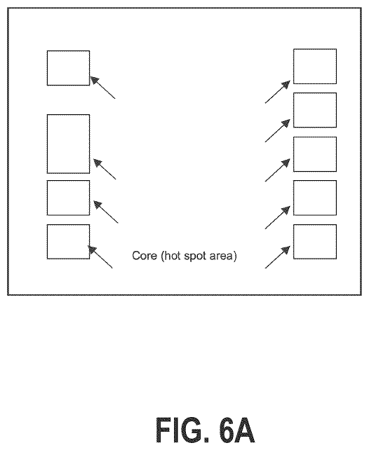

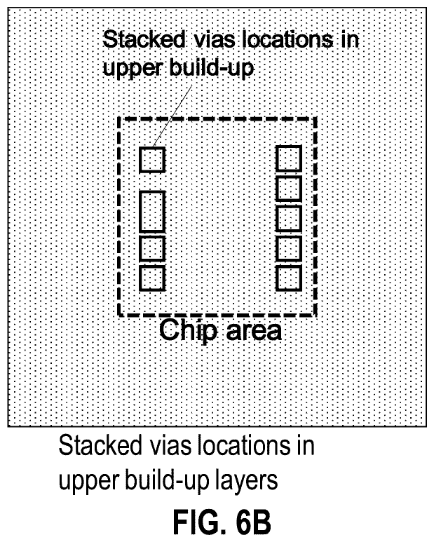

FIG. 6A illustrates a power map of a 3D chip, in accordance with an embodiment. FIG. 6B illustrates a top view of the stacked vias locations in a 3D chip, in accordance with an embodiment. In one embodiment, each of the plurality of stacked vias can have a diameter ranging from about 0.1 mm to about 1 mm, with larger diameter vias located in hotspot areas. The larger vias in the hot spot areas can enhance localized heat dissipation by providing a greater cross-sectional area for heat conduction away from regions of high thermal density. Such a targeted approach to thermal management can prevent overheating of critical components, maintain optimal operating temperatures, and improve the overall reliability and lifespan of the semiconductor device.

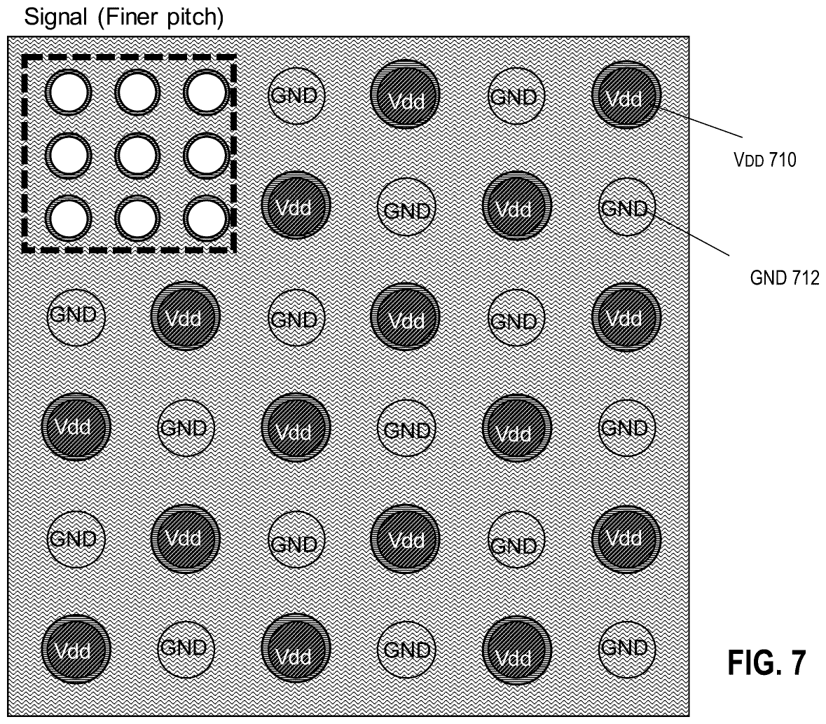

FIG. 7 illustrates a top view of the metal core of the semiconductor device for thermal management of a 3D chip, in accordance with an embodiment. In one embodiment, the top layer can include signal vias and lines. Such conductive pathways can facilitate the transmission of electrical signals between the chip and other components or layers within the device. Integrating signal vias and lines into the top layer can improve data transmission efficiency and maintain signal integrity by minimizing signal path lengths and reducing potential interference. Such a design can support high-speed communication and enhances the overall performance of the device while still contributing to effective heat management. In the case of a multi-core chip, where multiple processing cores are integrated onto a single semiconductor die, signal pathways are essential to enable effective communication between the cores and external interfaces. These processing cores need to exchange data and control signals rapidly to function cohesively and perform complex computational tasks efficiently. To accommodate this requirement, signal lines can be fabricated within the package substrate of the semiconductor device. The package substrate, which can also contain VDD and GND, provide a structured environment for embedding these signal lines without compromising the device's structural integrity. The signal lines can be designed as impedance-matched signal, which is an aspect of high-speed digital circuit design, involving the alignment of the signal line's characteristic impedance with that of the transmitting and receiving circuitry. The matching can minimize signal reflections and losses that can occur due to impedance discontinuities along the transmission path. Signal reflections can lead to interference, signal degradation, and increased error rates, which are detrimental to the performance of multi-core processors that rely on precise timing and signal integrity. By ensuring impedance matching, the signal lines can maintain high-quality signal transmission, reduce electromagnetic interference, and support reliable communication at the high data rates required by modern processors.

Additionally, the signal lines can be fabricated with a finer pitch than the through-holes used for VDD 710 and GND 712 connections. The pitch refers to the center-to-center spacing between adjacent signal lines. A finer pitch a mean that the signal lines are spaced closer together, allowing for a greater number of signal pathways to be accommodated within the same physical area of the package substrate. This can be particularly important in multi-core chips, which require a dense network of interconnections to manage the increased volume of data exchange between cores and with external components. By reducing the spacing between signal lines, more signals can be routed without expanding the size of the chip package, which facilitates maintaining a compact form factor in devices like smartphones, laptops, and other portable electronics.

By integrating impedance-matched signal lines with a finer pitch within the package substrates, the device can achieve a high-density interconnect structure that supports the complex communication needs of multi-core processors. Such a design can enable efficient data transfer and synchronization between cores, especially for parallel processing and maximizing the computational capabilities of the chip, and allowing for high-speed interfaces with external memory, peripherals, and other system components, contributing to the overall performance and responsiveness of the device. Furthermore, such an approach can optimize the use of available space within the package substrates.

The bottom layer can be responsible for distributing power supply voltages, e.g. VDDs, and ground connections, e.g., GND, to the lower layers of the device's structure in an appropriate and efficient manner. Such a distribution can ensure that all necessary components within the bottom layer can receive the required power and maintain a stable ground reference for the proper functioning of the device. By effectively routing VDDs and GNDs through the bottom layer, the device can achieve consistent voltage levels and minimizes electrical noise, contributing to improved performance and reliability.

The bottom layer, located beneath the primary active layers of the device, do not contribute to thermal management. The primary focus can be on meeting specific electrical and mechanical requirements essential for the device's operation and structural integrity. Vias and lines within the bottom layer can be fabricated based on precise electrical needs, such as signal routing, power distribution, and grounding paths. The features can ensure optimal electrical performance by reducing resistance, minimizing inductance, and preventing signal degradation. From a mechanical perspective, the vias and lines provide structural support, enhancing the device's ability to withstand mechanical stresses such as bending, vibration, and thermal expansion.

By concentrating on electrical connectivity and mechanical stability rather than thermal considerations, the bottom layer can simplify the device's overall design and manufacturing process and allow for efficient use of space within the device, enabling more compact designs without compromising performance.

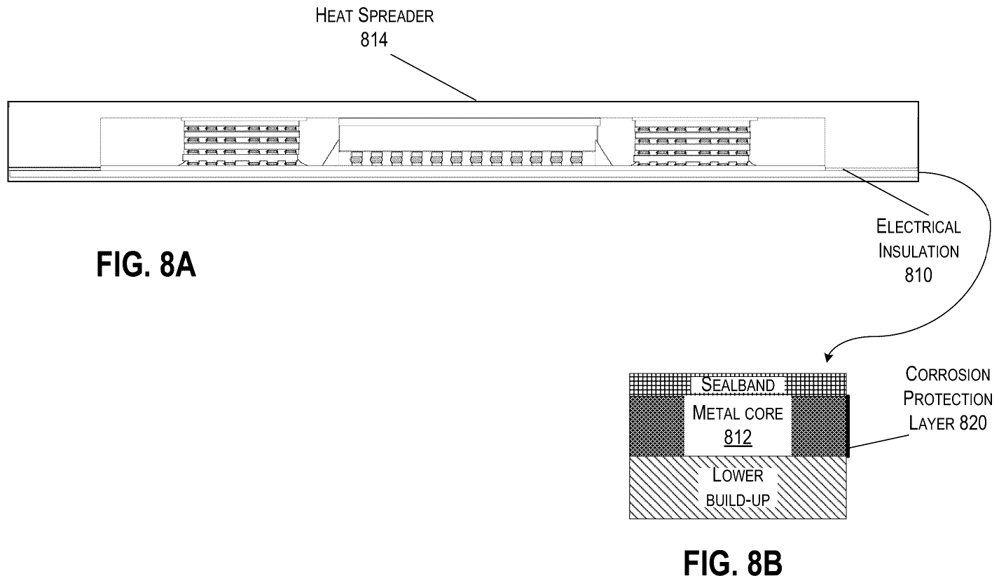

FIG. 8A illustrates a semiconductor device with insulated thermal interface materials, in accordance with an embodiment. FIG. 8B illustrates a cross section view of a package substrate of a semiconductor device with insulated thermal interface material, in accordance with an embodiment. In some embodiments, an electrical insulation 810 between the metal core 812 and the heat spreader 814 can be used. In such embodiments, the TIM 816 is electrically insulating to ensure that no unintended electrical currents flow between the metal core 812 and the heat spreader 814, which could otherwise lead to short circuits or interference with the device's operation. The electrically insulating TIM 816 can maintain the necessary thermal conductivity to efficiently transfer heat away from the chip while preserving electrical isolation. The combination of properties is used for devices where the metal core may be connected to sensitive circuitry or where electrical potentials differ between components.

At the edges of the metal core 812, applying a corrosion protection layer 820 can be performed to prevent degradation of the metal due to exposure to environmental factors such as moisture, oxygen, and chemicals that can cause oxidation or corrosion. Materials such as nickel/gold (Ni/Au), titanium (Ti), or benzotriazole (BTA) can be used as the corrosion protection layer 820. Nickel/gold plating can provide a barrier against oxidation and enhance solderability, which is beneficial during assembly processes. Titanium can form a stable oxide layer that protects the underlying metal from further corrosion, offering long-term durability. Benzotriazole, which is a package corrosion inhibitor, can chemically bond to copper surfaces, forming a protective film that prevents tarnishing and corrosion.

By incorporating the electrically insulating TIM 816, the device can ensure effective thermal management without compromising electrical isolation between the metal core 812 and heat spreader 814, which can facilitate maintaining the integrity of electrical signals and preventing potential malfunctions caused by unintended electrical pathways. The corrosion protection layer 820 at the metal core's edges can enhance the device's reliability and longevity by safeguarding against environmental degradation.

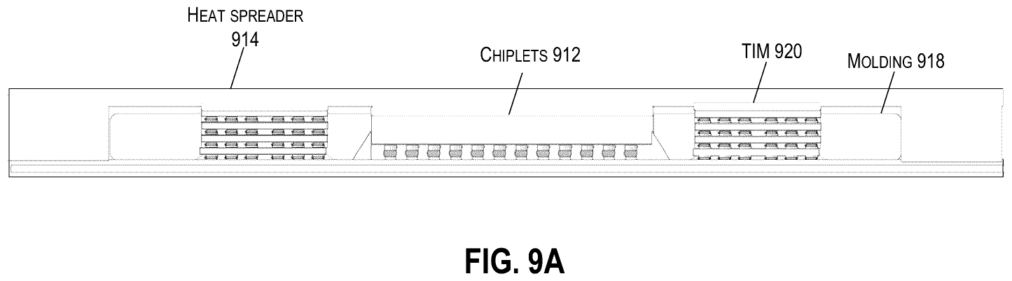

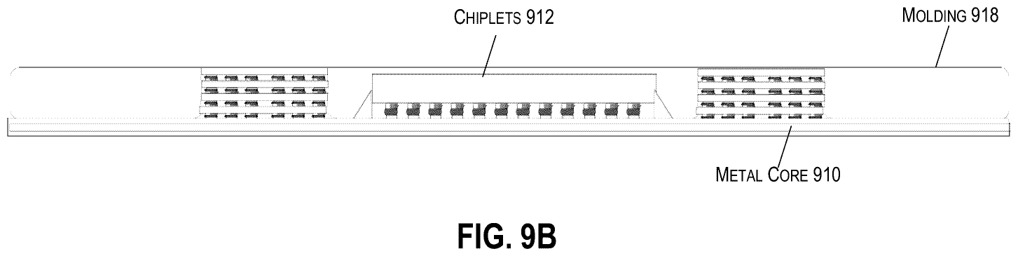

FIG. 9A-9B illustrate a semiconductor device with compensation of heigh variation of chiplets, in accordance with an embodiment. When the coefficient of thermal expansion (CTE) of a metal core 910 is low enough, molding and planarization processes during semiconductor fabrication become feasible. A low CTE means that the metal core 910 can expand and contract at a rate similar to the surrounding materials, such as the chiplets 912 and the molding compounds 918. Such a compatibility can reduce mechanical stresses and prevent warping or cracking during temperature changes. As a result, the height variation of chiplets 912 can be minimized because the planarization process can create a uniform surface across the chiplets and the substrate. Minimizing height variations can ensure consistent thermal and electrical contact between the chiplets and any overlying structures, such as heat spreader 914 or cooling modules. The uniformity can enhance the device's performance by improving heat dissipation and ensuring reliable electrical connections.

Conversely, when the CTE of a metal core 910 is high and differs significantly from that of the chiplets 912 and molding compounds 918, molding becomes impractical or impossible. The mismatch in thermal expansion can lead to significant mechanical stresses during thermal cycling, causing delamination, cracks, or other defects. In such embodiments, the height variation of chiplets 912 can become a concern because the lack of planarization means that the surface of the chiplets 912 is uneven. The unevenness can lead to poor thermal contact with the heat spreader or cooling solution and inconsistent electrical connections. The increased height variations can necessitate the use of thicker TIM 920 to fill the gaps between the chiplets 912 and the heat spreader 914, which can degrade thermal performance due to the TIM's relatively lower thermal conductivity compared to solid materials such as metals.

In a water cooling module, a water-cooling heatsink can be placed on top of the heat spreader 914, and compress the heat spreader 914 against the chiplets 912. The water-cooling module can include a flexible cold plate that can accommodate the height variations of the chiplets 912. The flexibility of the cold plate can allow it to conform to the uneven surface, ensuring good thermal contact across all chiplets. This compression compensates for the height differences, reducing the thickness of the TIM 920 and improving heat transfer efficiency. Water cooling can provide superior thermal performance due to water's high specific heat capacity and thermal conductivity, effectively removing heat from high-power devices. The ability of the flexible cold plate to adjust to height variations can enhance the overall thermal management of the device and maintains reliable operation even when molding and planarization are not possible.

In an air cooling module, a heatsink with fins can be rigid and cannot compress the heat spreader 914 to accommodate height variations of the chiplets 912. Since the heatsink cannot adjust to the uneven surface, the height variations are not compensated. This results in increased TIM thickness between the shorter chiplets and the heat spreader, leading to higher thermal resistance in those areas. The thermal performance of the TIM 920 can become more important because thicker TIM layers impede efficient heat transfer due to their lower thermal conductivity compared to metals. To mitigate this issue, high-performance TIMs with superior thermal conductivity can be used to minimize the thermal resistance caused by the increased thickness. However, even with advanced TIMs, the thermal performance may not match that of water-cooled systems, especially in high-power applications where efficient heat removal is essential. Therefore, controlling the height variation of chiplets is more important in air-cooled devices to ensure adequate thermal management and maintain the reliability and performance of the semiconductor device.

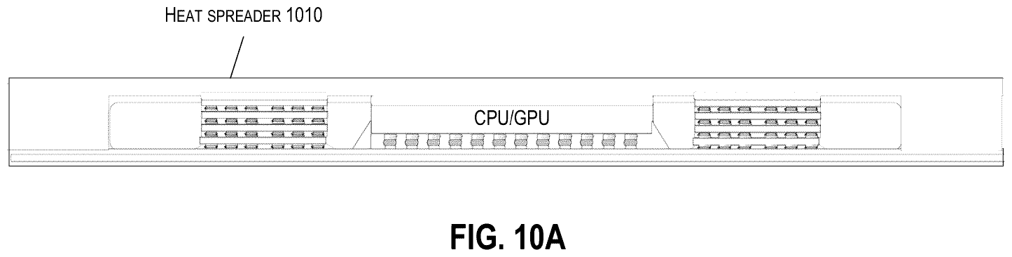

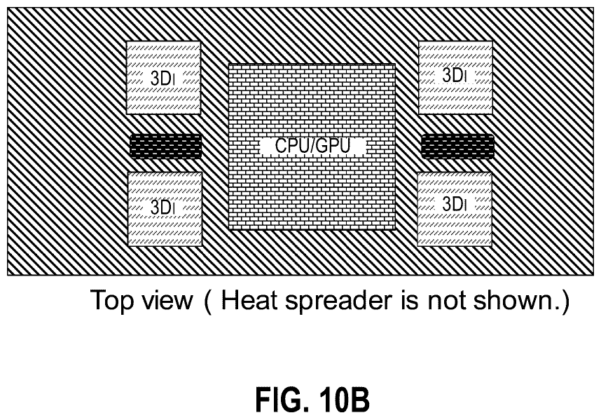

FIG. 10A illustrates a cross section view of a semiconductor device with additional heat spreader foots, in accordance with an embodiment. FIG. 10B illustrates a top view of a semiconductor device with additional heat spreader foots, in accordance with an embodiment.

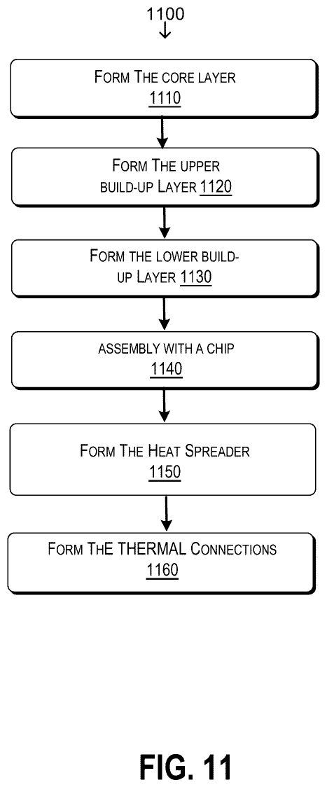

FIG. 11 illustrates a block diagram of a method 1100 for forming the semiconductor device, in accordance with some embodiments. As shown by block 1110, the package substrate is formed.

As shown by block 1120, the top layer is formed. The upper build-up layer can include a first plurality of power planes (VDD) and ground planes (GND) and a plurality of vias stacked vertically.

As shown by block 1130, the lower build-up layer is formed.

As shown by block 1140, the semiconductor device is assembled with a chip.

As shown by block 1150, the heat spreader layer is formed over the chip.

As shown by block 1160, thermal connections are established between the heat spreader and the package substrate on both ends of the package substrate.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a package substrate below a chip, the package substrate comprising:
upper build-up layers including a first plurality of power planes (VDD) and ground planes (GND) and a plurality of vias stacked vertically;
a core layer and
lower build-up layers including a second plurality of VDD and GND, and
a heat spreader over the chip,
wherein the heat spreader contacts the package substrate on both ends of the package substrate.

2. The semiconductor device of claim 1, wherein the heat spreader contacts the package substrate through a thermal interface material (TIM).

3. The semiconductor device of claim 1, wherein:
the core layer is a metal; and
the metal includes at least one of: Cu, CuMo, CuW, CuC, or graphite.

4. The semiconductor device of claim 1, wherein:
the core layer is a ceramic; and
the ceramic includes at least one of: AlN, SiC, BN, or BeO.

5. The semiconductor device of claim 1, wherein:
the core layer is a thermal conductor; and
the thermal conductor includes at least one of: diamond or silicon.

6. The semiconductor device of claim 1, wherein the plurality of stacked vias is configured to function as at least one of power or ground.

7. The semiconductor device of claim 1, wherein the upper build-up layers further includes signal vias and lines.

8. The semiconductor device of claim 1, wherein:
the core layer includes ground planes; and
the semiconductor device further comprises a dielectric layer between a power through-holes and the core layer.

9. The semiconductor device of claim 1, wherein:
the core layer includes power planes; and
the semiconductor device further comprises a dielectric layer between a ground through-holes and the core layer.

10. The semiconductor device of claim 1, wherein:
the core layer includes signal-through-holes; and
the semiconductor device further comprises a dielectric layer between the signal-through-holes and the core layer.

11. The semiconductor device of claim 1, wherein:
vias located in hot spot areas have larger diameters than vias located in other areas.

12. The semiconductor device of claim 1, wherein the core layer includes materials selected based on at least one of: a thermal conductivity, mechanical properties, a coefficient of thermal expansion, or a Young's modulus and electrical properties.

13. The semiconductor device of claim 1, wherein:
the core layer includes a set of cuts; and
the set of cuts are electrically and thermally isolated from each other.

14. The semiconductor device of claim 1, wherein at least portions of a metal or a ceramic or a diamond or a Si is embedded in at least one of: a top layer, or in a core of a package substrate below the chip.

15. A method of fabricating a semiconductor device, the method comprising:
forming a package substrate below a chip, comprising:
forming upper build-up layers including a first plurality of power planes (VDD) and ground planes (GND) and a plurality of vias stacked vertically;
forming a core layer; and
forming lower build-up layers including a second plurality of VDD and GND,
forming a heat spreader over the chip; and
establishing thermal connections between the heat spreader and the package substrate on both ends of the package substrate.

16. The method of claim 15, further comprising:
forming a dielectric layer between a set of contacts and the core layer, wherein the set of contacts includes at least one of: ground-through-holes, power-through-holes, or signal-through-holes.

17. The method of claim 15, wherein:
the core layer is a metal; and
the metal includes at least one of: Cu, CuMo, CuW, CuC, or graphite.

18. The method of claim 15, wherein:
the core layer is a ceramic; and
the ceramic includes at least one of: AlN, SiC, BN, or BeO.

19. The method of claim 15, wherein the core layer is a thermal conductor, wherein the thermal conductor includes at least one of: diamond or silicon.

20. A semiconductor device, comprising:
upper build-up layers including a first plurality of power planes (VDD) and ground planes (GND) and a plurality of stacked vias;
a core layer; and
lower build-up layers including a second plurality of VDD and GND.
